(19) United States
(12) Patent Application Publication
(10) Pub. No.: US 2015/0027501 A1
(43) Pub. Date: Jan. 29, 2015

(54) SUBSTRATE CLEANING METHOD AND SUBSTRATE CLEANING APPARATUS

(71) Applicant: Tokyo Electron Limited, Tokyo (JP)

(72) Inventors: Kazuya Dobashi, Nirasaki City (JP); Kensuke Inai, Nirasaki City (JP)

(21) Appl. No.: 14/340,026

(22) Filed: Jul. 24, 2014

(30) Foreign Application Priority Data
Jul. 26, 2013 (JP) 2013-156138

(51) Int. Cl. H01L 21/02

(52) U.S. Cl. CPC H01L 21/02046; H01L 21/02057
USPC 134/31; 15/303

(57) ABSTRACT

In order to remove the particles attached to the wafer W, the distance between a front end of a nozzle unit 4 and the wafer W is set to be in a range of from about 10 mm to about 100 mm, a pressure within a cleaning chamber 31 is set to be an adequate level, and then, a gas cluster is irradiated to a surface of the wafer W. Therefore, the particles are rapidly removed with high efficiency. Further, since the gas cluster is vertically irradiated to the surface of the wafer W from the nozzle unit 4, damage of a recess pattern is suppressed. Furthermore, by supplying a mixed gas containing a carbon dioxide gas and a helium gas to the nozzle unit 4 and generating the gas cluster, the particles are removed with high efficiency.

### CROSS-REFERENCE TO RELATED APPLICATION

This application claims the benefit of Japanese Patent Application No. 2013-156138 filed on Jul. 26, 2013, the disclosures of which are incorporated herein by reference.

### TECHNICAL FIELD

The embodiments described herein pertain generally to a technology of cleaning a surface of a substrate by irradiating a gas cluster to the substrate.

### BACKGROUND

In a semiconductor manufacturing apparatus, adsorption of particles to a substrate during a manufacturing process has become one of major factors that affect a yield of products. For this reason, the substrate is cleaned before or after a process is performed on the substrate. However, there has been a demand for development of a cleaning technology capable of clearly removing particles by a simple method while suppressing damage to the substrate. As a cleaning technology which has been under research and development, there is a method of separating particles from a surface of a substrate by applying a physical shear force greater than an adsorption force between the particles and the substrate, and for example, as described in Patent Document 1, there is a technology in which a physical shear force of a gas cluster is used.

A gas cluster refers to an aggregate (cluster) of multiple atoms or molecules held together by discharging a high-pressure gas in a vacuum and cooling the gas to a condensation temperature through adiabatic expansion. When a substrate is cleaned, this gas cluster is irradiated to the substrate as it is or as it is adequately accelerated, and then, particles are removed.

A gas cluster is generated by being irradiated through a dedicated nozzle, and, thus, an irradiation area thereof is limited. For this reason, if a gas cluster is applied to a process performed on a large-diameter area such as a semiconductor wafer (hereinafter, referred to as “wafer”) having a diameter of 300 mm, improvement in throughput is a problem to be solved, and particle removal performance per cluster nozzle needs to be improved.

As a method of improving particle removal performance of a gas cluster, there is, for example, a technology of ionizing a gas cluster and irradiating the ionized gas cluster to a substrate (gas cluster ion beam). According to this method, when a generated gas cluster is ionized, molecules constituting the gas cluster are repulsive to each other, and by using such a property, an irradiation diameter of the gas cluster is increased. Thus, a higher throughput can be obtained. However, there has been a problem that a large-scale apparatus is needed to generate a gas cluster ion beam.

In Patent Document 2, it is described that a gas cluster is irradiated to a periphery of a substrate from a position of 10 mm right above from a surface of the substrate through a gas cluster nozzle slanted with respect to the surface of the substrate. However, Patent Document 2 is different from the present example embodiments in configuration.

Patent Document 1: Japanese Patent Laid-open Publication No. 2013-026327 Patent Document 2: Japanese Patent Laid-open Publication No. 2012-216636 (Paragraphs [0026] and [0036])

### SUMMARY

In view of the foregoing, example embodiments provide a technology capable of rapidly removing particles with high efficiency when particles attached to a substrate are removed by irradiating a gas cluster to the substrate.

In one example embodiment, a substrate cleaning method of removing particles attached to a substrate includes providing the substrate to face a nozzle unit; generating a gas cluster as an aggregate of atoms or molecules of a cleaning gas through adiabatic expansion by discharging the cleaning gas to a processing gas atmosphere as a vacuum atmosphere through the nozzle unit from a region having a higher pressure than the processing gas atmosphere in which the substrate is provided; and removing the particles by vertically irradiating the gas cluster to a surface of the substrate. Further, in the irradiating of the gas cluster, a distance between a front end of the nozzle unit and the substrate is in a range of from about 10 mm to about 100 mm.

In another example embodiment, a substrate cleaning apparatus of removing particles attached to a substrate includes a cleaning chamber configured to accommodating a substrate therein and perform a cleaning process on the substrate in a vacuum atmosphere; and a nozzle unit configured to discharge a cleaning gas toward the substrate within the cleaning chamber from a region having a higher pressure than an atmosphere in which the substrate is accommodated and configured to generate a gas cluster as an aggregate of atoms or molecules of the cleaning gas through adiabatic expansion. Further, a distance between a front end of the nozzle unit and the substrate is in a range of from about 10 mm to about 100 mm, and the nozzle unit is provided to vertically irradiate the gas cluster to a surface of the substrate.

In accordance with the example embodiments, in order to remove the particles attached to the substrate, while setting the distance between the front end of the nozzle unit and the substrate to be in a range of from about 10 mm to about 100 mm, the gas cluster as the aggregate of atoms or molecules of the cleaning gas is vertically irradiated to the surface of the substrate from the nozzle unit. Therefore, it is possible to rapidly remove the particles with high efficiency.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plane view illustrating a configuration of a vacuum processing apparatus in accordance with an example embodiment;

FIG. 2 is a longitudinal cross-sectional view of a substrate cleaning apparatus provided in the vacuum processing apparatus;

FIG. 3 is a longitudinal cross-sectional view illustrating an example of a nozzle unit of the substrate cleaning apparatus;

FIG. 4 is a configuration view illustrating a control unit provided in the vacuum processing apparatus;

FIG. 5 is a longitudinal cross-sectional view illustrating recesses formed at a substrate;

FIG. 6A to FIG. 6D are side views illustrating a status where a particle is removed by a gas cluster;

FIG. 7A to FIG. 7D are side views illustrating a status where a particle is removed by a gas cluster;

FIG. 8 is a characteristic graph illustrating a pressure distribution within a cleaning chamber after irradiation of a gas cluster;

FIG. 9 is a characteristic graph illustrating a correlation between a pressure within the cleaning chamber and particle removal rate;

FIG. 10 is a characteristic graph illustrating a correlation between a pressure within the cleaning chamber and particle removal rate;

FIG. 11 is a characteristic graph illustrating a correlation between a pressure on a primary side of the nozzle unit and particle removal rate;

FIG. 12 is a characteristic graph illustrating a correlation between a pressure on a primary side of the nozzle unit and particle removal rate;

FIG. 13 is a characteristic graph illustrating a correlation between a flow rate ratio of helium in a mixed gas and a cluster beam intensity; and

FIG. 14 is a characteristic graph illustrating a correlation between a distance from a gas cluster irradiation position depending on a nozzle clearance and remaining particle amount.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

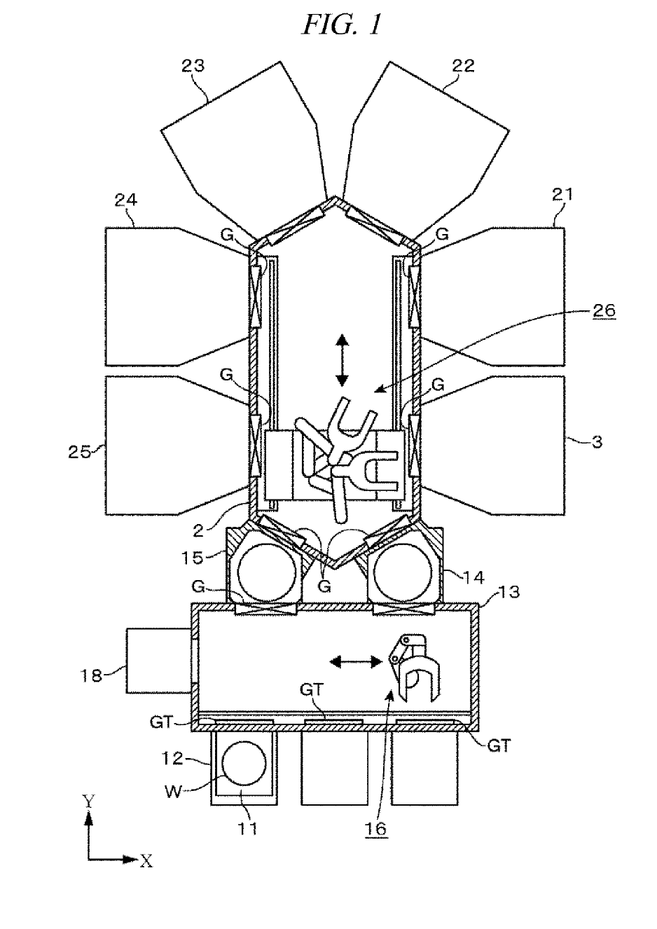

A vacuum processing apparatus including a substrate cleaning apparatus of performing a substrate cleaning method in accordance with a first example embodiment will be explained. FIG. 1 is a plane view illustrating the overall configuration of a vacuum processing apparatus having a multi-chamber system. In the vacuum processing apparatus, loading/unloading ports 12 through which a FOUP 11 is mounted are transversely arranged in parallel at, for example, three positions. Here, the FOUP 11 serves as a sealed transfer container accommodating, for example, 25 sheets of substrates, i.e., wafers W, therein. Further, an atmospheric transfer chamber 13 is provided along the arrangement of the loading/unloading ports 12, and at a front wall of the atmospheric transfer chamber 13, a gate door GT to be opened and closed together with a cover of each FOUP 11 is provided.

At a real wall of the atmospheric transfer chamber 13 (i.e., opposite side with respect to the loading/unloading ports 12), for example, two load-lock chambers 14 and 15 are airtightly connected. In these load-lock chambers 14 and 15, non-illustrated vacuum pumps and leak valves are provided, so that a normal pressure atmosphere and a vacuum atmosphere are switched to each other. Further, G in FIG. 1 denotes a gate valve.

Further, in the atmospheric transfer chamber 13, a first substrate transfer unit 16 configured to transfer the wafer W is provided. Furthermore, at a left wall of the atmospheric transfer chamber 13 as viewed from the front side thereof toward the rear side thereof, an alignment chamber 18 configured to adjust a direction of the wafer or eccentricity thereof is provided. The first substrate transfer unit 16 is configured to transfer the wafer W with respect to the FOUPs 11, the load-lock chambers 14 and 15, and the alignment chamber 18. The first substrate transfer unit 16 is further configured to be moved, for example, in the arrangement direction (X-axis direction in FIG. 1) of the FOUPs 11, vertically moved, rotated around a vertical axis, and moved back and forth.

At opposite side of the load-lock chambers 14 and 15 with respect to the atmospheric transfer chamber 13, a vacuum transfer chamber 2 is airtightly connected. The vacuum transfer chamber 2 is airtightly connected to each of a cleaning module 3 serving as a substrate cleaning apparatus and multiple, for example, five vacuum processing modules 21 to 25. The vacuum processing modules 21 to 25 are configured to perform, for example, a sputtering process or a CVD process for film formation.

The vacuum transfer chamber 2 includes a second substrate transfer unit 26 configured to transfer the wafer W in a vacuum atmosphere. The second substrate transfer unit 26 includes a multi-joint arm configured to be rotated around a vertical axis and moved back and forth. The arm is configured to be also moved in a longitudinal direction (Y-axis direction in FIG. 1). The substrate transfer unit 26 is configured to transfer the wafer W with respect to each of the load-lock chambers 14 and 15, the cleaning module 3, and each of the vacuum processing modules 21 to 25.

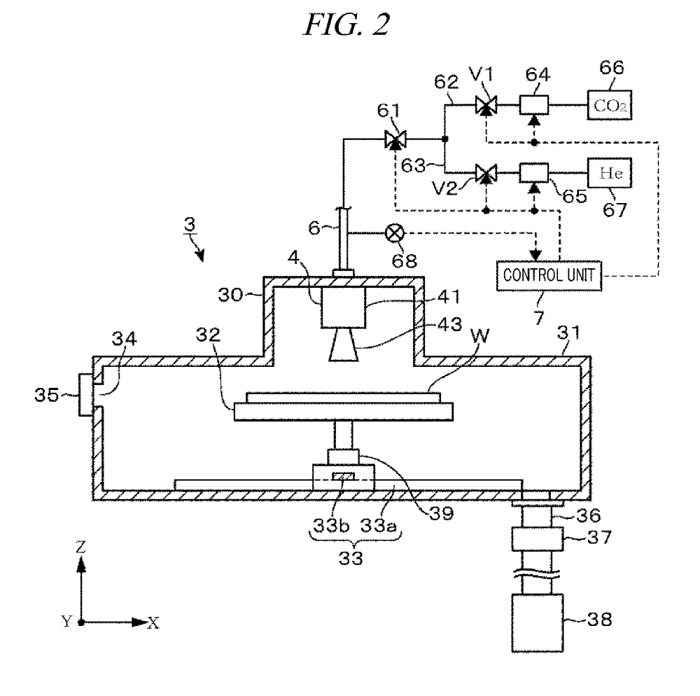

Hereinafter, the cleaning module 3 will be described with reference to FIG. 2. This cleaning module 3 includes a cleaning chamber 31 configured as a decompression chamber (vacuum chamber). Within the cleaning chamber 31, there is provided a mounting table 32 configured to mount the wafer W in a horizontal posture. A reference numeral 34 in FIG. 2 denotes a transfer opening, and a reference numeral 35 denotes a gate valve configured to open/close the transfer opening.

By way of example, on a bottom surface of the cleaning chamber 31 at a position adjacent to the transfer opening 34, there are provided supporting pins (not illustrated) to pass through through-holes formed in the mounting table 32. Under the mounting table 32, a non-illustrated elevating unit configured to elevate the supporting pins is provided. The supporting pins and the elevating unit are configured to transfer the wafer W between the second substrate transfer unit 26 and the mounting table 32. The bottom surface of the cleaning chamber 31 is connected to one end of an exhaust path 36 configured to exhaust an atmosphere within the cleaning chamber 31, and the other end of the exhaust path 36 is connected to a vacuum pump 38 via a pressure control unit 37 such as a butterfly valve or the like.

The mounting table 32 is configured to be moved in a horizontal direction by a driving unit 33. The driving unit 33 includes an X-axis rail 33a horizontally extended along an inner side of the cleaning chamber 31 from the transfer opening 34 (X-axis direction) and a Y-axis rail 33b horizontally extended along a direction from a paper front surface to a paper rear surface (Y-axis direction) in FIG. 2, under the mounting table 32 on the bottom surface of the cleaning chamber 31. The Y-axis rail 33b is configured to be movable along the X-axis rail 33a. Above the Y-axis rail 33b, the mounting table 32 is provided via an elevation unit 39, and the mounting table 32 is configured to be moved in the X-axis and Y-axis directions by the driving unit 33 and also vertically moved by the elevation unit 39. Further, in the mounting table 32, there is provided a non-illustrated temperature controller configured to control a temperature of the wafer W mounted on the mounting table 32.

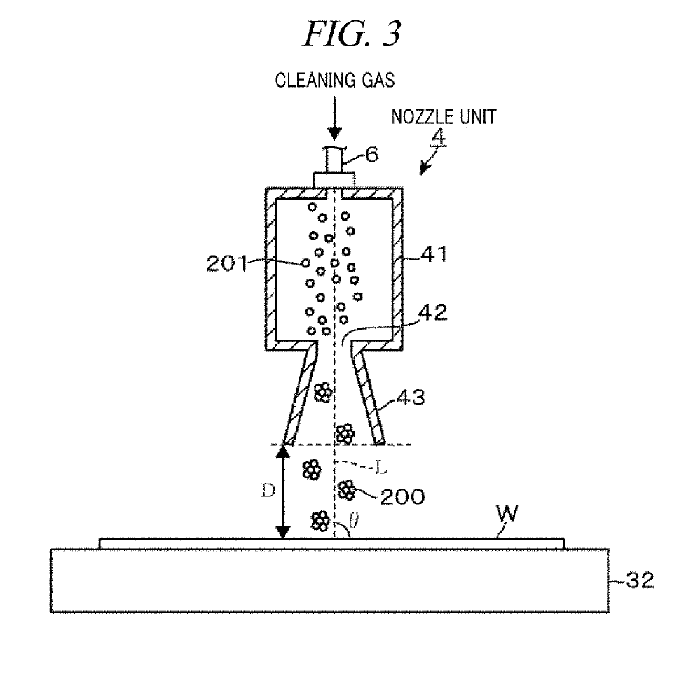

At a central portion of a ceiling surface of the cleaning chamber 31, an upward protrusion 30 is formed. At this protrusion 30, a nozzle unit 4 configured to irradiate a gas cluster is provided. The nozzle unit 4 is configured to irradiate a cleaning gas from a region having a higher pressure than a processing gas atmosphere within the cleaning chamber 31 toward the wafer W within the cleaning chamber 31, and configured to generate a gas cluster as an aggregate of atoms or molecules of the cleaning gas through the adiabatic expansion. This nozzle unit 4 includes a schematically cylindrical pressure chamber 41 of which a lower end is open, as depicted in FIG. 3. The lower end of the pressure chamber 41 is formed into an orifice 42. The orifice 42 is connected to a gas diffusion unit 43 of which a diameter is increased downwardly. An opening diameter (a diameter of an opening) of the orifice 42 is within a range of desirably from about 0.05 mm to about 0.2 mm, for example, about 0.1 mm.

Further, the nozzle unit 4 is provided to vertically irradiate the gas cluster toward a surface of the wafer W as described above. Herein, the expression “vertically irradiate” refers to, for example, a status where an angle (θ) formed by a central axis L in a longitudinal direction of the nozzle unit 4 and the mounting surface (the surface of the wafer W) of the mounting table 32 is within a range of about 90°±15°, as depicted in FIG. 3. Furthermore, a clearance D from a front end of the nozzle unit 4 to the surface of the wafer W mounted on the mounting table 32 is set to from about 10 mm to about 100 mm, desirably from about 20 mm to about 100 mm, and more desirably from about 50 mm to about 100 mm.

An upper end of the pressure chamber 41 is connected to one end of a gas supply line 6 extended to pass through a ceiling surface of the cleaning chamber 31, as depicted in FIG. 2. The other end of the gas supply line 6 is branched into a first branch line 62 and a second branch line 63. Between a branch point of the first branch line 62 and the second branch line 63 and the one end of the gas supply line 6, a pressure control valve 61 is provided. An upstream side of the first branch line 62 is connected to a carbon dioxide (CO₂) supply source 66 via an opening/closing valve V1 and a flow rate control unit 64. Further, an upstream side of the second branch line 63 is connected to a helium (He) gas supply source 67 via an opening/closing valve V2 and a flow rate control unit 65. Further, at the gas supply line 6, a pressure detection unit 68 configured to detect a pressure within the gas supply line 6 is provided.

The carbon dioxide gas is a cleaning gas, and a gas cluster is generated from this gas. The helium gas is difficult to form a gas cluster, but as described below, the helium gas may suppress collisions between the gas cluster and the carbon dioxide molecules by reducing a partial pressure of the carbon dioxide gas within the cleansing chamber 31, and may also improve a generation speed of the gas cluster from the carbon dioxide. At the gas supply line 6, the pressure detection unit 68 configured to detect a pressure within the gas supply line 6 is provided, and based on a detection value from this pressure detection unit 68, an opening degree of the pressure control valve 61 is adjusted by a control unit 7 to be described later, so that a gas pressure within the pressure chamber 41 is controlled. The pressure detection unit 68 may detect a pressure within the pressure chamber 41.

Further, the pressure control based on the detection value from the pressure detection unit 68 may be carried out by controlling a gas flow rate by the carbon dioxide gas flow rate control unit 64 and the helium gas flow rate control unit 65. Furthermore, after a supply pressure is increased by a boosting device such as a gas booster between each of the opening/closing valves V1 and V2 and the pressure control valve 61, the pressure control may be performed by the pressure control valve 61.

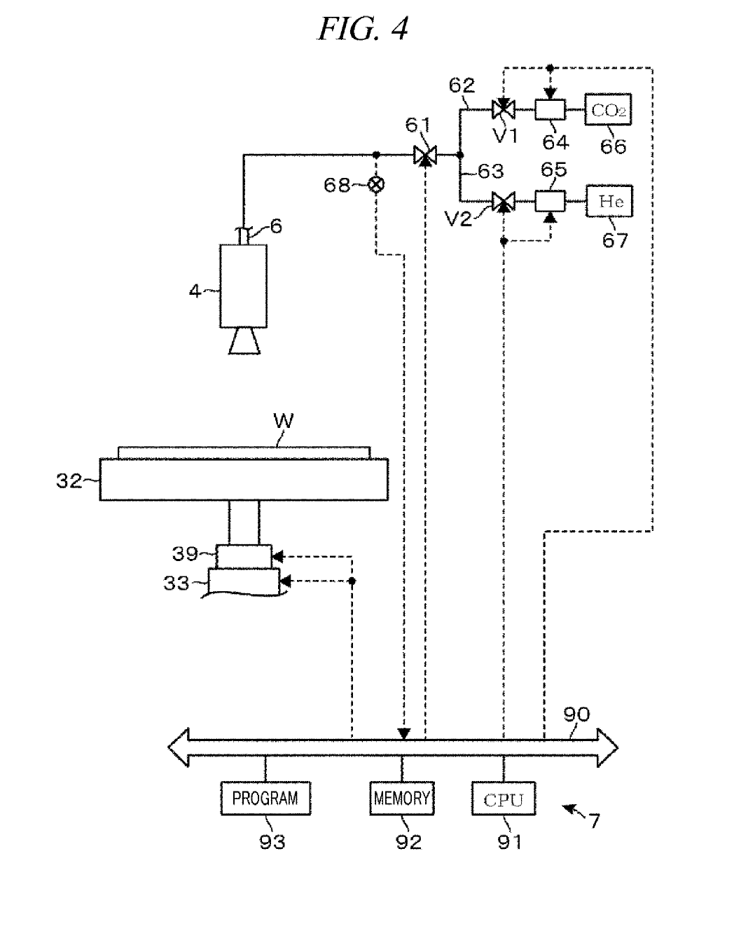

Further, in the cleaning module 3, the control unit 7 is provided as depicted in FIG. 4. A reference numeral 90 in FIG. 4 denotes a bus, and the bus 90 is connected to a CPU 91, a memory 92, and a program 93 for executing each process of the following operation to be carried out by the cleaning module 3. Based on the program 93, this control unit 7 outputs control signals for controlling the elevating unit 39 and the driving unit 33 of the mounting table 32 or for controlling the pressure control valve 61, the opening/closing valves V1 and V2, and the flow rate control units 64 and 65 based on the detection values from the pressure detection unit 68. Further, this program 93 may be recorded in, for example, a compact disc, a hard disk, an optical magneto-optical disc, and the like, and installed in the control unit 7.

The overall process of the vacuum processing apparatus on the wafer W will be described briefly. After the FOUP 11 is mounted on the loading/unloading port 12, the wafer W is unloaded from the FOUP 11 by the first substrate transfer unit 16. This wafer W has an interlayer insulating film thereon. This interlayer insulating film includes, for example, recesses (grooves and via-holes) for burying a copper wiring as a recess pattern.

The wafer W loaded from the FOUP 11 is transferred to the alignment chamber 18 through the atmospheric transfer chamber 13, and then, alignment is carried out. Thereafter, the wafer W is transferred to the cleaning module 3 through the first substrate transfer unit 16, the load-lock chambers 14 and 15 and the second substrate transfer unit 26, and then, a particle is removed.

The wafer W from which particles are removed in the cleaning module 3 is transferred by the second substrate transfer unit 26 to the vacuum processing modules 21 to 25, and then, a barrier layer is formed or a CVD process is carried. Thereafter, the wafer W is transferred to the vacuum transfer chamber 2, the load-lock chambers 14 and 15, and the atmospheric transfer chamber 13 in sequence, and then, returned back to, for example, the original FOUP 11 mounted on the loading/unloading port 12.

Hereinafter, an operation of the cleaning module 3 in accordance with an example embodiment will be explained. A height position is set in advance such that the clearance D between the nozzle unit 4 and the wafer W is, for example, 100 mm. The wafer W is loaded into the cleaning module 3 by the second substrate transfer unit 26, and then, mounted on the mounting table 32 by the cooperation between the non-illustrated supporting pins and the second substrate transfer unit 26. Then, the horizontal position of the wafer W is determined by the driving unit 33, and the wafer W is moved such that a gas cluster irradiation starting position on the surface of the wafer W becomes a gas cluster irradiation position (a directly below position) of the nozzle unit 4. In this example embodiment, the gas cluster irradiation position is set to be a peripheral position of the wafer W.

Then, a mixed gas, in which a carbon dioxide gas and a helium gas are mixed at a flow rate ratio of 1:1, is discharged from the nozzle unit 4 toward the gas cluster irradiation starting position on the wafer W to generate a gas cluster. Assuming that in the nozzle unit 4, an upstream side of the orifice 42 is a primary side and a downstream side thereof is a secondary side, a supply pressure as a pressure at the primary side of the nozzle unit 4 is within a range of desirably from about 0.5 MPa to about 5.0 MPa, more desirably from about 0.9 MPa to about 5.0 MPa, and is set to, for example, about 4 MPa. Further, a pressure of a processing gas atmosphere within the cleaning chamber 31 as the secondary side of the nozzle unit 4 is set up to about 200 MPa.

The flow rates of the carbon dioxide gas and the helium gas are adjusted to preset values by the flow rate control units 64 and 65, respectively. Further, the pressure control valve 61 and the opening/closing valves V1 and V2 are opened, so that the mixed gas containing the carbon dioxide gas and the helium gas is supplied into the nozzle unit 4. When the carbon dioxide gas is supplied as the processing gas atmosphere from the nozzle unit 4 having a high pressure to the cleaning chamber 31 having a low pressure, it is cooled to a condensation temperature or less through the rapid adiabatic expansion, and, thus, as depicted in FIG. 3, molecules 201 are bonded together by the van der Waals force to form a gas cluster 200 as an aggregate of the molecules 201.

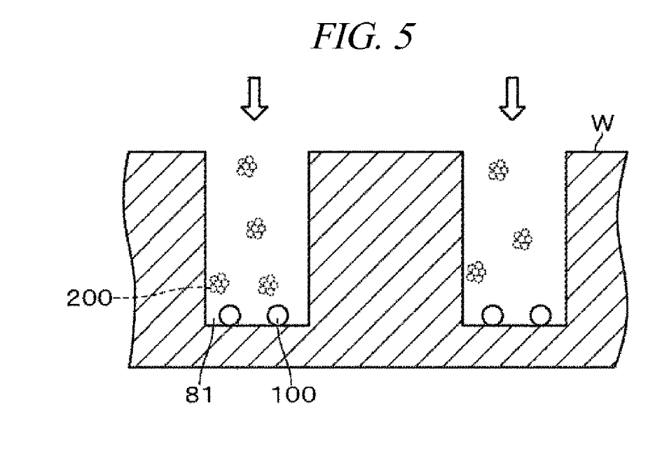

The gas cluster 200 from the nozzle unit 4 is vertically irradiated toward the wafer W, and as depicted in FIG. 5, the gas cluster 200 is introduced into recesses 81 for a circuit pattern of the wafer W to remove particles 100 within the recesses 81.

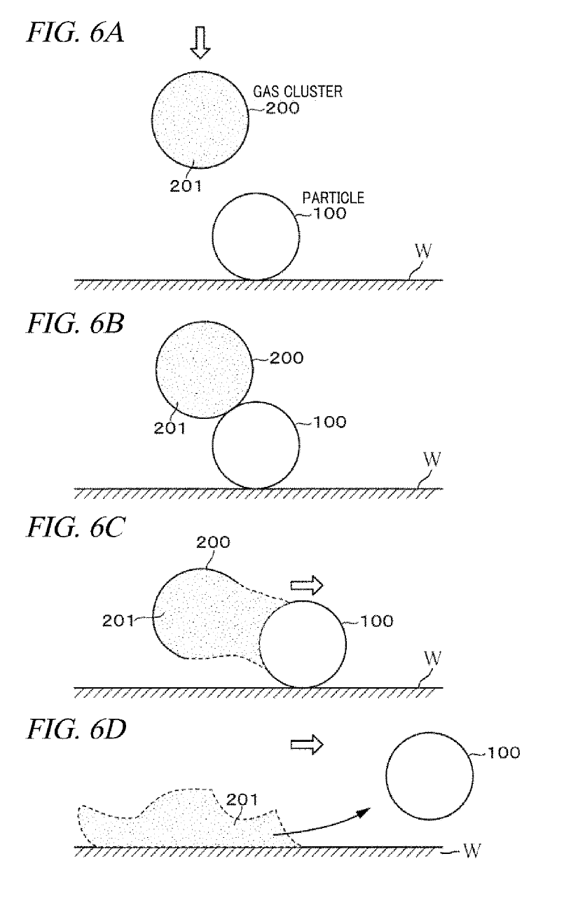

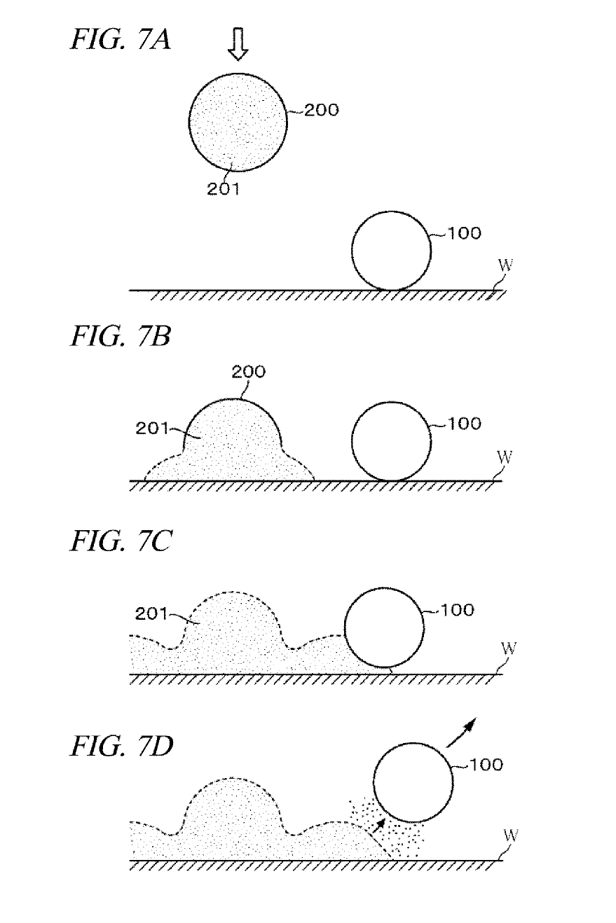

FIG. 6A to FIG. 7D schematically illustrate a status where the particle 100 on the wafer W is removed by the gas cluster 200. FIG. 6A to FIG. 6D show a case where the gas cluster 200 collides with the particle 100 on the wafer W. In this case, the gas cluster 200 is vertically irradiated to the surface of the wafer W as depicted in FIG. 6A and may be collided with, for example, an upper edge portion of the particle 100. If the gas cluster 200 collides with the particle in an offset state (in a state where a center of the gas cluster 200 is deviated from a center of the particle 100 when viewed from the top) as depicted in FIG. 6B, a force that transversely pushes away the particle 100 is applied to the particle 100 due to the impact at the time of being collided as depicted in FIG. 6C. As a result, the particle 100 is separated from the surface of the wafer W, and is blown away in a side or diagonally upward direction as depicted in FIG. 6D.

Further, the gas cluster 200 may be irradiated to the vicinity of the particle 100 as depicted in FIG. 7A to FIG. 7D without being directly collided with the particle 100 to remove the particle 100. As depicted in FIG. 7A, when the gas cluster 200 collides with the wafer W, the constituent molecule 201 is transversely dispersed and decomposed (see FIG. 7B). Herein, a high kinetic energy density region is moved transversely (horizontally), and, thus, the particle 100 is separated and blown from the wafer W (see FIG. 7C and FIG. 7D). As such, the particle 100 comes out of the recess 81 and is scattered within the cleaning chamber 31 in a vacuum atmosphere, so that the particle 100 is removed to the outside of the cleaning chamber 31 through the exhaust path 36.

Meanwhile, since a circuit integration density is increased, a width of a protrusion between the adjacent recesses on the wafer W is very small, but the gas cluster is vertically irradiated to the surface of the wafer W, and, thus, damage of the protrusion, so-called pattern collapse, is suppressed.

Then, while the gas cluster is irradiated from the nozzle unit 4, the mounting table 32 is moved in the horizontal direction to sequentially move a position where the gas cluster is irradiated on the surface of the wafer W. Thus, the gas cluster may be irradiated to the entire surface of the wafer W, and particles attached to the entire surface of the wafer W may be removed.

Herein, based on a result of simulation, if the nozzle unit 4 and the wafer W are somewhat close to each other, a gas cluster is irradiated to the wafer W and then, molecules of carbon dioxide constituting the gas cluster may stay in the vicinity of the irradiation position. As a result, a gas concentration in the vicinity of the surface of the wafer W may be increased.

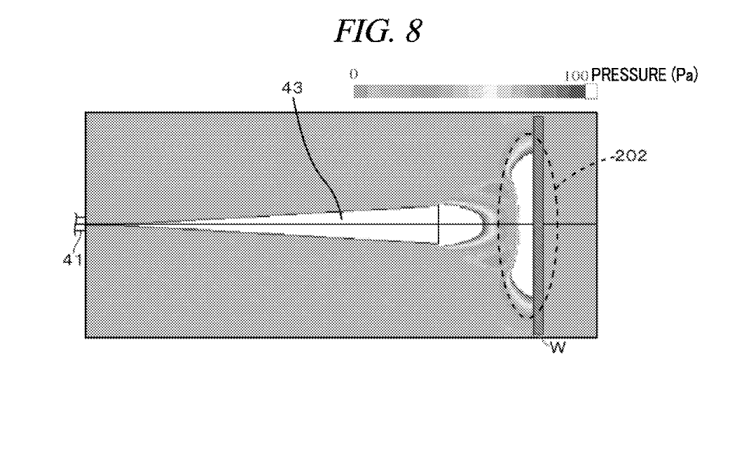

FIG. 8 is a diagram of a pressure distribution within the cleaning chamber 31 in the case where the clearance D between the nozzle unit 4 and the wafer W is set to about 10 mm, a pressure at the primary side of the nozzle unit 4 is set to about 4 MPa, a pressure of the cleaning chamber 31 is set to about 35 Pa, and a gas cluster is irradiated from the nozzle unit 4. It can be seen from this pressure distribution diagram that a molecule collection region 202 of the carbon dioxide gas is formed in the vicinity of a region, to which the gas cluster is irradiated, on the surface of the wafer W. This molecule collection region 202 of the carbon dioxide gas refers to a region where a carbon dioxide gas concentration is locally high in the vicinity of the surface of the wafer W since carbon dioxide molecules, which straightly fly without forming a gas cluster, collide with the wafer W.

In a region where a concentration of a residual gas is high as described above, the possibility of the collision between the gas cluster and the carbon dioxide gas molecules is increased. If the carbon dioxide gas molecules collide with the gas cluster formed of carbon dioxide, some carbon dioxide molecules constituting the gas cluster are separated from the aggregation thereof due to the impact of the collision. As a result, the number of constituent molecules of the gas cluster is decreased, and, kinetic energy thereof is decreased.

Meanwhile, if the nozzle unit 4 and the wafer W are somewhat away from each other, the carbon dioxide molecules which do not constitute the gas cluster collide with the wafer W is easy to be diffused and the carbon dioxide molecules on the surface of the wafer W is difficult to be left. Accordingly, the molecule collection region 202 of the carbon dioxide gas is not substantially formed. Therefore, in this case, in the gas cluster discharged from the nozzle unit 4 toward the wafer W, since the possibility of a collision between the carbon dioxide gas molecules, which stay in the vicinity of the substrate surface without forming the gas cluster, and a carbon dioxide gas molecule group of the gas cluster is decreased, it is possible to suppress a decrease in the kinetic energy thereof.

Further, since the gas cluster is radially irradiated from the orifice 42 of the nozzle unit 4, as the nozzle unit 4 is farther away from the wafer W, an irradiation area on the surface of the wafer W is increased. Therefore, if the clearance D between the nozzle unit 4 and the wafer W is increased, an area to be cleaned by one-time irradiation of the gas cluster is increased, which is advantageous in terms of throughput improvement.

However, if the nozzle unit 4 is too far away from the wafer W, a moving distance until the gas cluster reaches the wafer W in the processing gas atmosphere is increased. Thus, even if a concentration of the carbon dioxide gas remaining in the processing gas atmosphere is low, the possibility of a collision with the carbon dioxide gas is increased. For this reason, in order to decrease the frequency of the collision, a pressure of the processing gas atmosphere needs to be considerably lowered and a vacuum pump having a high exhausting capacity needs to be used. However, this may cause the equipment to be large in scale, and cost may be increased, which is not advisable.

Accordingly, the clearance D between the nozzle unit 4 and the wafer W needs to be not too great or not too small, but needs to have an adequate value. The clearance D is within a range of desirably from about 10 mm to about 100 mm, more desirably from about 20 mm to about 100 mm, and still more desirably from about 50 mm to about 100 mm in accordance with the following experimental example. Further, if the clearance D is set, an operation of removing particles on the wafer W by the gas cluster is influenced by a pressure of the processing gas atmosphere, as can be clearly seen from the following experimental example.

In this example embodiment, a desirable pressure range of the processing gas atmosphere is evaluated based on the particle removal rate under the following specific conditions. That is, when a pressure of the processing gas atmosphere varies and the gas cluster is irradiated to a sample substrate, for example, the wafer W, for 1 second at each pressure, the removal rate of particles attached to the sample substrate is obtained. Based on the result, a pressure at which the high particle removal rate is obtained is obtained.

The particle removal rate refers to the percentage of the reduced number of particles after irradiating the gas cluster with respect to the number of particles before irradiating the gas cluster when the gas cluster is irradiated to an evaluation region of the sample substrate for about 1 second. That is, assuming that the number of particles within the evaluation region before irradiating the gas cluster is n1 and the number of particles within the evaluation region after irradiating the gas cluster is n2, the particle removal rate can be expressed by {(n1−n2)/n1}×100. When the particle removal rate is evaluated, the silica particles of about Φ23 nm are used as the particles and the evaluation region is a square region, having a side of about 7 μm, around a position at a central axis L of the nozzle unit 4 on the surface of the sample substrate. The particles are counted with, for example, a SEM (Scanning Electron Microscope). Before irradiating the gas cluster, the number of particles attached to the evaluation region is, for example, 150 to 200. Even if all the particles do not have the same particle diameter of about 23 nm, the same result can be obtained as long as the particle has a diameter within a range of, for example, from about 10 nm to about 100 nm. Further, the determination that a pressure is set to a pressure level in which particle removal rate is about 50% or more also includes a case where even if there is used another method in which particles are not made of silica and the particles have diameters out of the above range, it is natural to determine that a pressure is set to the above-described pressure level based on a result of the another method.

In this example embodiment, an adequate pressure range of the processing gas atmosphere is determined as a pressure range in which the particle removal rate is about 50% or more. Meanwhile, the gas discharged from the nozzle unit 4 contains the helium gas as well as the carbon dioxide gas. A function of the helium gas is as follows.

Within the cleaning chamber 31, a pressure is set to a preset value by a vacuum pump. For this reason, if the gas discharged from the nozzle unit 4 is a mixed gas containing the carbon dioxide gas and the helium gas, helium gas molecules are smaller than carbon dioxide molecules constituting the gas cluster. Thus, even if the gas cluster collides with the helium gas molecules, the gas cluster is not broken. For this reason, the kinetic energy of the whole gas cluster is suppressed from being decreased, and, thus, the high particle removal rate can be obtained. Further, the helium gas can accelerate the carbon dioxide gas. Therefore, as compared with a case where the helium gas is not added, the kinetic energy of the gas cluster may be increased. However, if there is too much helium gas, a partial pressure of the carbon dioxide gas discharged from the nozzle unit 4 becomes too low. In such case, since the frequency of collisions between the carbon dioxide molecules required for gas cluster generation is decreased, the number of gas clusters is decreased, so that the cleaning effect is reduced. For this reason, a desirable mixing ratio P of the helium gas in the gas to be supplied to the nozzle unit 4 satisfies 0%<P≦95%, and a more desirable mixing ratio P satisfies 10%≦P≦90%. Further, it is effective even if a gas cluster is generated by discharging a carbon dioxide gas only from the nozzle unit 4 instead of the mixed gas.

Therefore, although the adequate pressure range of the processing gas atmosphere is described as up to about 200 Pa, it is an adequate pressure range for a case where the mixing ratio of the helium gas in the gas to be supplied to the nozzle unit 4 is about 50%. Since the adequate pressure range is influenced by the mixing ratio of the helium gas, a pressure of the processing gas atmosphere may be appropriately selected depending on the mixing ratio. Further, if the particle removal rate is about 50% or more, the cleaning module 3 using the gas cluster can be regarded as an apparatus capable of performing a high cleaning effect with a high throughput. Further, it is more desirable that the particle removal rate is about 80% or more.

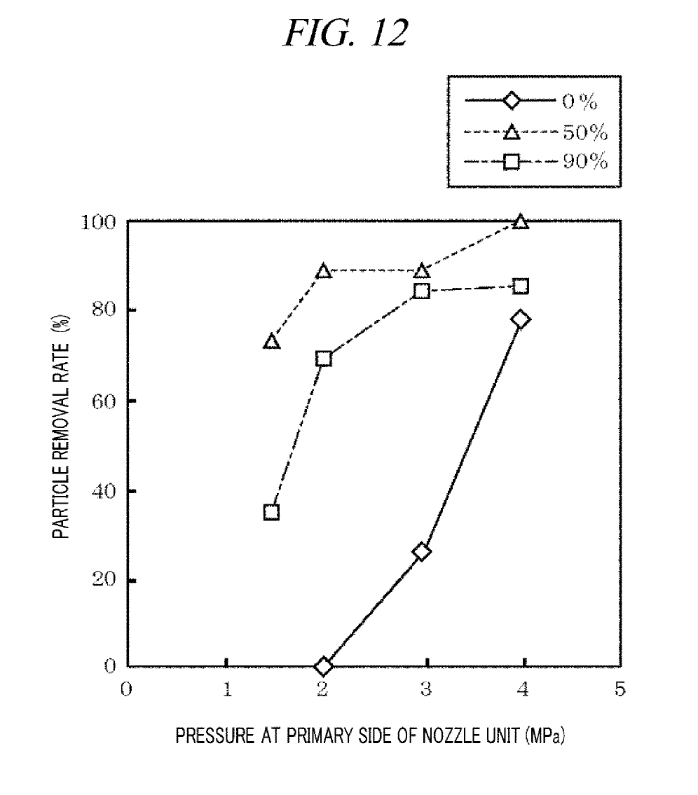

By way of example, if the clearance D is about 100 mm and the mixing ratio of helium in the gas to be supplied to the nozzle unit 4 is about 90%, the pressure range in which the particle removal rate is about 80% or more is from about 3 MPa to about 5 MPa as shown in FIG. 12 to be explained below.

Further, if the pressure at the primary side of the nozzle unit 4 is increased, the firm gas cluster can be generated, but if the pressure is too high, the surface of the wafer W may be damaged. On the other hand, if the pressure at the primary side of the nozzle unit 4 is too low, the gas cluster to be irradiated from the nozzle unit 4 is not firm and cannot sufficiently remove particles. For this reason, the pressure at the primary side of the nozzle unit 4 is set to be in a range of desirably from about 0.5 MPa to about 5 MPa, and more desirably, from about 0.9 MPa to about 5 MPa.

In the above-described example embodiment, in order to remove particles attached to the wafer W, a distance between the front end of the nozzle unit 4 and the wafer W is set to be in a range of from about 10 mm to about 100 mm, and the pressure within the cleaning chamber 31 is set to an adequate level. Therefore, it is possible to rapidly remove particles with high efficiency. Further, since the gas cluster is vertically irradiated to the surface of the wafer W from the nozzle unit 4, damage of the recess pattern can be suppressed. Furthermore, since the mixed gas containing the carbon dioxide gas and the helium gas is used as the cleaning gas to be supplied to the nozzle unit 4, the kinetic energy of the gas cluster is high. Therefore, it is possible to remove particles with higher efficiency.

Further, in the example embodiment, a particle detecting device may be connected to the atmospheric transfer chamber 13 depicted in FIG. 1. In this case, for example, location information of particles attached to the surface of the wafer W is acquired by the particle detecting device, and based on the location information of particles, the control unit 7 may control a gas cluster to be locally irradiated toward the particle-attached location on the surface of the wafer W. Furthermore, the substrate cleaning apparatus in accordance with the example embodiment may be, for example, a so-called stand-alone substrate cleaning apparatus as an independent apparatus instead of being provided within the vacuum processing apparatus depicted in FIG. 1. Moreover, as for the gas cluster irradiation position, the nozzle unit 4 may be moved while scanning the surface of the wafer W, or the nozzle unit 4 may be relatively moved with respect to the mounting table 32.

The recess pattern is not limited to grooves or the like for burying a copper wiring formed in the interlayer insulating film, and may be, for example, a resist pattern where a resist film is formed in addition to a region corresponding to the wiring burying position. Further, the gas for gas cluster generation is not limited to carbon dioxide, and may be, for example, argon (Ar).

### Experimental Example 1

### Correlation Among Nozzle Clearance, Pressure within Cleaning Chamber 31, and Particle Removal Rate

Hereinafter, the clearance D between the front end of the nozzle unit 4 and the surface of the substrate will be referred to as “nozzle clearance” for convenience of explanation. In order to obtain a correlation among a nozzle clearance, a pressure within the cleaning chamber 31, and particle removal rate, the following test is carried out. With the cleaning module depicted in FIG. 2, the clearance D is set to seven values, i.e., about 10 mm, about 30 mm, about 50 mm, about 60 mm, about 70 mm, about 80 mm, and about 100 mm. The pressure within the cleaning chamber 31 is set to three values, i.e., about 20 Pa, about 150 Pa, and about 300 Pa for each nozzle clearance. Under each condition, a gas cluster is irradiated toward a sample substrate for about 1 second, and the particle removal rate is checked. Further, as a gas for cluster generation, a mixed gas containing carbon dioxide and helium at a preset flow rate ratio of 1:1 is used. A pressure at the primary side of the nozzle unit 4 is set to about 4 MPa.

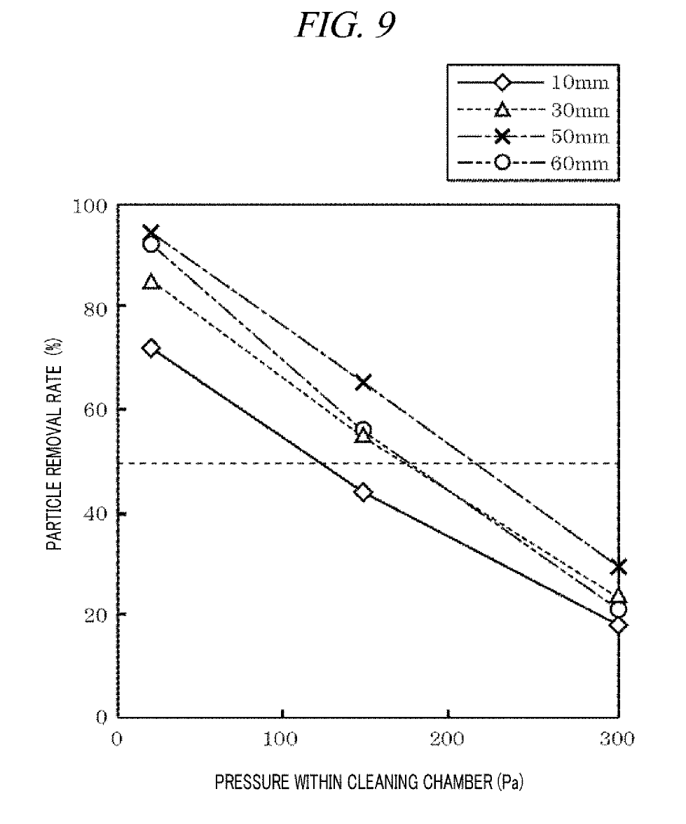

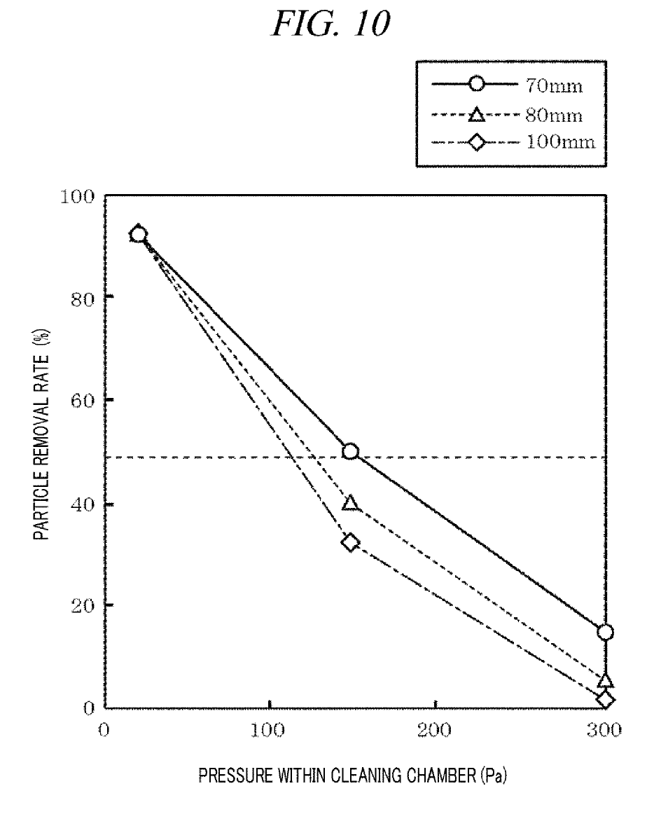

FIG. 9 shows a result of a case where the clearance D is set to be in a range of from about 10 mm to about 60 mm, and FIG. 10 shows a result of a case where the nozzle clearance is set to be in a range of from about 70 mm to about 100 mm. According to these results, it can be seen that as the pressure within the cleaning chamber 31 is lowered, the particle removal rate is increased. Further, when the pressure within the cleaning chamber 31 is as low as about 20 Pa, if the nozzle clearance is set to be large, the particle removal rate is increased. Meanwhile, when the pressure within the cleaning chamber 31 is increased to about 300 Pa, if the nozzle clearance is set to be large, the particle removal rate tends to be decreased, and when the nozzle clearance is set to about 60 mm or more, as the nozzle clearance is increased, the particle removal rate is decreased. As described above, if the nozzle clearance is increased, the frequency of collisions between the gas cluster irradiated from the nozzle unit 4 and the residual gas is increased. Therefore, the particle removal rate is greatly influenced by the pressure of the processing gas atmosphere.

Therefore, when a target particle removal rate is about 50% or more, in order to achieve the target efficiency, if the nozzle clearance is set to about 10 mm, about 80 mm, and about 100 mm, the pressure within the cleaning camber 31 needs to be set to about 120 Pa or less; if the nozzle clearance is set to about 30 mm and about 60 mm, the pressure within the cleaning camber 31 needs to be set to about 170 Pa or less; if the nozzle clearance is set to about 70 mm, the pressure within the cleaning camber 31 needs to be set to about 150 Pa or less; and if the nozzle clearance is set to about 50 mm, the pressure within the cleaning camber 31 needs to be set to about 200 Pa or less. According to this result, by comparison between a graph in the case where the nozzle clearance is set to about 10 mm and a graph in the case where the nozzle clearance is set to about 30 mm, it can be expected that the case where the nozzle clearance is set to about 30 mm is more preferable to the case where the nozzle clearance is set to about 10 mm.

Further, when the nozzle clearance is set to about 100 mm and the gas cluster is irradiated toward the sample substrate for about 0.2 second, the particle removal rate is higher than about 80%. When the nozzle clearance is set to about 10 mm, it takes about 1 second to obtain the particle removal rate of about 80%. Therefore, by adjusting the nozzle clearance, a time required for removing the particles can be reduced.

### Experimental Example 2

### Correlation Among Pressure at Primary Side of Nozzle Unit 4, Nozzle Clearance, and Particle Removal Rate

Then, when the nozzle clearance is set to about 10 mm and the pressure at the primary side of the nozzle unit 4 is set to about 2 MPa, about 3 MPa, and about 4 MPa with the cleaning module 3 depicted in FIG. 2, the gas cluster is irradiated and the particle removal rate is checked. Further, when the nozzle clearance is set to about 100 mm and the pressure at the primary side of the nozzle unit 4 is set to about 3 MPa, the particle removal rate is shown. The gas cluster is irradiated for about 60 seconds. Furthermore, as the cleaning gas, a carbon dioxide gas is used, and the pressure within the cleaning chamber 31 is set to up to about 30 Pa.

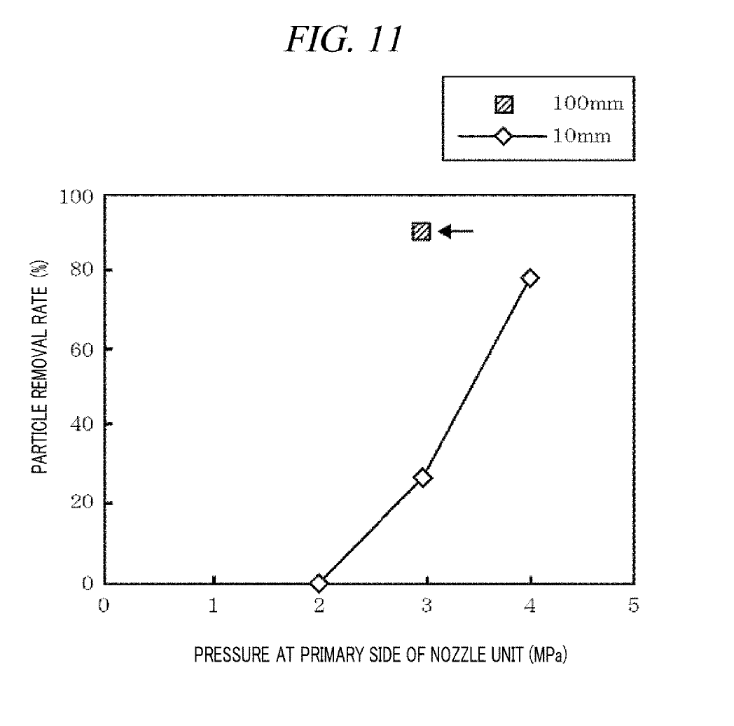

FIG. 11 shows this result and is a characteristic graph illustrating the pressure at the primary side of the nozzle unit 4 on the horizontal axis and the particle removal rate on the vertical axis. According to this result, when the nozzle clearance is set to about 10 mm and the pressure at the primary side of the nozzle unit 4 is about 2 MPa, the particle removal rate is almost zero, and when the pressure at the primary side of the nozzle unit 4 is set to about 3 MPa, the particle removal rate is about 30%. As the pressure at the primary side of the nozzle unit 4 is increased, the particle removal rate is increased, and when the pressure at the primary side of the nozzle unit 4 is set to about 4 MPa, the particle removal rate is about 80%. Therefore, by increasing the pressure at the primary side of the nozzle unit 4, the particle removal rate can be increased. Further, when the nozzle clearance is set to about 100 mm and the pressure at the primary side of the nozzle unit 4 is set to about 3 MPa, the particle removal rate is about 80%. Accordingly, by setting the nozzle clearance to be from about 10 mm to about 100 mm, the particle removal rate can also be increased.

### Experimental Example 3

### Correlation Between Mixing Ratio of Helium Gas and Particle Removal Rate

Then, when a mixed gas containing a carbon dioxide gas and a helium gas is discharged from the nozzle unit 4 in the cleaning module 3 depicted in FIG. 2, a mixing ratio of the helium gas and particle removal rate are checked.

The mixed gas containing the carbon dioxide gas and the helium gas is supplied as the cleaning gas to the nozzle unit 4 to generate the gas cluster. When a flow rate ratio of the helium gas in the mixed gas is set to 2 values, i.e., about 50% and about 90%, and a pressure at the primary side of the nozzle unit 4 is set to about 1.5 MPa, about 2 MPa, about 3 MPa, and about 4 MPa for each flow rate ratio, the gas cluster is irradiated toward a sample substrate and the particle removal rate is checked. Further, irradiation time of the gas cluster is set to about 60 seconds and the nozzle clearance is set to about 10 mm. Furthermore, when the gas to be supplied to the nozzle unit 4 contains the carbon dioxide gas only, it is regarded that the flow rate ratio is about 0%. Moreover, when the pressure at the primary side of the nozzle unit 4 is set to about 2 MPa, about 3 MPa, and about 4 MPa, the gas cluster is irradiated toward the sample substrate and the particle removal rate is checked. The pressure within the cleaning chamber 31 is set to up to about 30 Pa.

FIG. 12 shows this result and is a characteristic graph illustrating a correlation between the pressure at the primary side of the nozzle unit 4 and the particle removal rate when the flow rate ratio of the helium gas (flow rate of helium gas/(flow rate of helium gas+flow rate of carbon dioxide gas)×100) is set to about 0%, about 50%, and about 90%.

According to this result, even when the mixed gas containing the carbon dioxide gas and the helium gas is used as a gas for generating a cluster, by setting the pressure at the primary side of the nozzle unit 4 to be high, the particle removal rate when the gas cluster is irradiated can be increased. Further, as compared with a case where only a carbon dioxide gas is used as a gas for generating a cluster, when a gas cluster is generated with the mixed gas containing the helium gas and the carbon dioxide gas, the particle removal rate is increased. Furthermore, it is understood that even when the mixing ratio is set to about 90%, good particle removal rate can be obtained since the frequency of collisions between the gas cluster formed of carbon dioxide and the residual gas within the apparatus is decreased and the generation speed of the gas cluster is improved.

Further, when the pressure at the primary side of the nozzle unit 4 is set to 3 values, i.e., about 2 MPa, about 3 MPa, about 4 MPa, and a ratio of a flow rate of the helium gas to a flow rate of the mixed gas is set to the following values for each pressure, a gas cluster is generated and a cluster beam intensity is measured.

2 MPa: 0%, 25%, 50%, 70%, 80%, 90%

3 MPa: 0%, 25%, 50%, 60%, 70%, 80%, 90%

4 MPa: 0%, 10%, 20%, 30%, 40%, 50%, 60%, 80%, 90%

Further, as for the cluster beam intensity, a pressure gauge (ion gauge) is provided on a gas cluster beam axis to measure a pressure value. Further, a difference between the measured pressure value and a pressure value at a position deviated from the gas cluster beam axis is defined as the cluster beam intensity. Furthermore, the pressure within the cleaning chamber 31 is set to up to about 30 Pa.

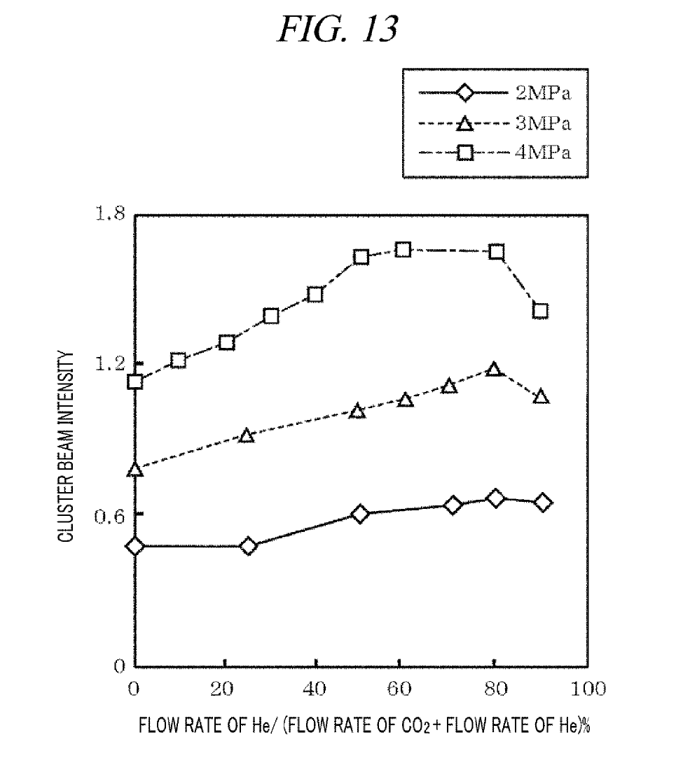

FIG. 13 shows this result and is a characteristic graph illustrating a correlation between the flow rate ratio (expressed as a percentage) of the helium gas in the mixed gas and the cluster beam intensity when the pressure at the primary side of the nozzle unit 4 is set to about 2 MPa, about 3 MPa, and about 4 MPa.

According to this result, when the flow rate ratio of the helium gas in the mixed gas is within a range of from about 0% to about 80%, by increasing the flow rate ratio of the helium gas in the mixed gas, a cluster beam intensity is increased. However, it can be seen that when the flow rate ratio of the helium gas in the mixed gas is about 90%, the cluster beam intensity is decreased. This is because if there is too much helium gas, a partial pressure of the carbon dioxide gas becomes too low as described above, so that the frequency of collisions between the carbon dioxide molecules for gas cluster generation is decreased, and, thus, the number of gas clusters is decreased. Therefore, the flow rate ratio of the helium gas is desirably about 95% or less, and more desirably, less than 90%.

### Experimental Example 4

### Correlation Between Nozzle Clearance and Area of Particle Removal Region

With the cleaning module 3 depicted in FIG. 2, a correlation between the nozzle clearance and the particle removal region on the substrate is investigated. The nozzle clearance is set to 3 values, i.e., about 10 mm, about 50 mm, and about 100 mm, and the mixed gas containing the carbon dioxide gas and the helium gas mixed at a flow rate ratio of 1:1 is used as a gas for generating a cluster. The pressure at the primary side of the nozzle unit 4 is set to about 4 MPa, and the pressure within the cleaning chamber 31 is set to up to about 30 Pa.

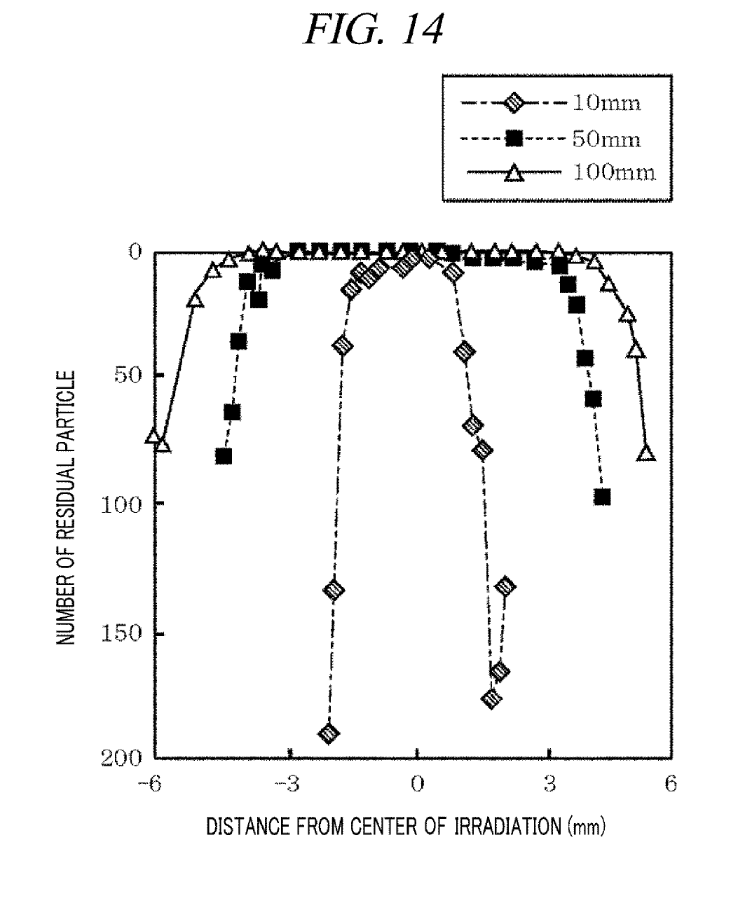

After a gas cluster is irradiated toward a sample substrate for about 60 seconds for each nozzle clearance, the number of particles remaining in a square region of about 7 μm×7 μm on a straight line passing through a center of the gas cluster irradiation on a surface of the sample substrate is checked. FIG. 14 shows this result, and the horizontal axis denotes a distance from the center of the gas cluster irradiation on the straight line and the vertical axis denotes the number of residual particles after irradiating the gas cluster. Further, the number of particles before irradiating the gas cluster is set to be in a range of from about 150 to about 200 for each position.

When the nozzle clearance is set to about 50 mm, the particles are removed from a wider region as compared with a case where the nozzle clearance is set to about 10 mm. Further, when the nozzle clearance is set to about 100 mm, the particles are removed from a still wider region.

Therefore, in order to reduce a cleaning time for each sheet of the wafer W with a single nozzle unit 4, it may be advantageous to increase the nozzle clearance.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A substrate cleaning method of removing particles attached to a substrate, the substrate cleaning method comprising:
providing the substrate to face a nozzle unit;
generating a gas cluster as an aggregate of atoms or molecules of a cleaning gas through adiabatic expansion by discharging the cleaning gas to a processing gas atmosphere as a vacuum atmosphere through the nozzle unit from a region having a higher pressure than the processing gas atmosphere in which the substrate is provided; and
removing the particles by vertically irradiating the gas cluster to a surface of the substrate;
wherein, in the irradiating of the gas cluster, a distance between a front end of the nozzle unit and the substrate is in a range of from about 10 mm to about 100 mm.

2. The substrate cleaning method of claim 1,
wherein the substrate has thereon a recess pattern.

3. The substrate cleaning method of claim 1,
wherein the distance between the front end of the nozzle unit and the substrate is in a range of from about 20 mm to about 100 mm.

4. The substrate cleaning method of claim 1,
wherein the distance between the front end of the nozzle unit and the substrate is in a range of from about 50 mm to about 100 mm.

5. The substrate cleaning method of claim 1,
wherein a pressure at a secondary side of the nozzle unit is set such that a removal rate of silica particles each having a diameter of from about 10 nm to about 100 nm on the substrate is about 50% or more when the gas cluster is irradiated for about 1 second to a square region, having a side of about 7 μm, around a position at a central axis of the nozzle unit.

6. The substrate cleaning method of claim 5,
wherein the pressure at the secondary side of the nozzle unit is set such that the removal rate of the silica particles is about 80% or more.

7. The substrate cleaning method of claim 1,
wherein the gas cluster is an aggregate of carbon dioxide gas molecules.

8. The substrate cleaning method of claim 1,
wherein the cleaning gas contains a helium gas.

9. The substrate cleaning method of claim 8,
wherein a ratio of a flow rate of the helium gas to a total flow rate of the cleaning gas is more than about 0% and about 95% or less.

10. The substrate cleaning method of claim 1,
wherein a pressure at a primary side of the nozzle unit is in a range of from about 0.9 MPa to about 5.0 MPa.

11. A substrate cleaning apparatus of removing particles attached to a substrate, the substrate cleaning apparatus comprising:
a cleaning chamber configured to accommodating a substrate therein and perform a cleaning process on the substrate in a vacuum atmosphere; and
a nozzle unit configured to discharge a cleaning gas toward the substrate within the cleaning chamber from a region having a higher pressure than an atmosphere in which the substrate is accommodated and configured to generate a gas cluster as an aggregate of atoms or molecules of the cleaning gas through adiabatic expansion,
wherein a distance between a front end of the nozzle unit and the substrate is in a range of from about 10 mm to about 100 mm, and the nozzle unit is provided to vertically irradiate the gas cluster to a surface of the substrate.

12. The substrate cleaning apparatus of claim 11,
wherein the distance between a front end of the nozzle unit and the substrate is in a range of from about 20 mm to about 100 mm.

13. The substrate cleaning apparatus of claim 11,
wherein the distance between a front end of the nozzle unit and the substrate is in a range of from about 50 mm to about 100 mm.

14. The substrate cleaning apparatus of claim 11,
wherein a pressure at a secondary side of the nozzle unit is set such that a removal rate of silica particles each having a diameter of from about 10 nm to about 100 nm on the substrate is about 50% or more when the gas cluster is irradiated for about 1 second to a square region, having a side of about 7 μm, around a position at a central axis of the nozzle unit.

15. The substrate cleaning apparatus of claim 14,
wherein the pressure at the secondary side of the nozzle unit is set such that the removal rate of the silica particles is about 80% or more.

16. The substrate cleaning apparatus of claim 11,
wherein the gas cluster is an aggregate of carbon dioxide gas molecules.

17. The substrate cleaning apparatus of any one of claim 11,
wherein the cleaning gas contains a helium gas.

18. The substrate cleaning apparatus of claim 17,
wherein a ratio of a flow rate of the helium gas to a total flow rate of the cleaning gas is more than about 0% and about 95% or less.

19. The substrate cleaning apparatus of claim 11,
wherein a pressure at a primary side of the nozzle unit is in a range of from about 0.9 MPa to about 5.0 MPa.
